(19) United States
(12) Patent Application Publication
(10) Pub. No.: US 2024/0372009 A1
(43) Pub. Date: Nov. 7, 2024

(54) SEMICONDUCTOR DEVICE HAVING DOUBLE-GATE STRUCTURE AND METHOD OF MANUFACTURING THE SAME, AND ELECTRONIC APPARATUS

(71) Applicant: INSTITUTE OF MICROELECTRONICS, CHINESE ACADEMY OF SCIENCES, Beijing (CN)

(72) Inventor: Huilong ZHU, Poughkeepsie, NY (US)

(21) Appl. No.: 18/565,701

(22) PCT Filed: Nov. 26, 2021
(86) PCT No.: PCT/CN2021/133509

§ 371 Date: Nov. 30, 2023

(30) Foreign Application Priority Data
Aug. 27, 2021 (CN) 202111000215.X

(51) Int. Cl. H01L 29/786; H01L 21/225; H01L 21/784; H01L 29/06; H01L 29/40; H01L 29/423; H01L 29/66; H01L 29/775

(52) U.S. Cl. CPC H01L 29/78696; H01L 29/0676; H01L 29/42384; H01L 29/66439; H01L 29/66742; H01L 29/775; H01L 29/78642; H01L 29/78648; H01L 21/225; H01L 21/784; H01L 29/0611; H01L 29/401

(57) ABSTRACT

A semiconductor device having a double-gate structure and a method of manufacturing the same, and an electronic apparatus including the semiconductor device are provided. The semiconductor device may include: a vertical channel portion on a substrate; source/drain portions respectively located at upper and lower ends of the channel portion relative to the substrate; and a first gate stack and a second gate stack on opposite sides of the channel portion in a first direction lateral to the substrate. A distance between an upper edge and/or a lower edge of an end of the first gate stack facing the channel portion in a vertical direction and a corresponding source/drain portion may be less than a distance between a corresponding upper edge and/or a corresponding lower edge of an end of the second gate stack facing the channel portion in the vertical direction and a corresponding source/drain portion.

### CROSS REFERENCE TO RELATED APPLICATION(S)

This application is a Section 371 National Stage Application of International Application No. PCT/CN2021/133509, filed on Nov. 26, 2021, which claims priority to Chinese Patent Application No. 202111000215.X, filed on Aug. 27, 2021 and entitled “SEMICONDUCTOR DEVICE HAVING DOUBLE-GATE STRUCTURE AND METHOD OF MANUFACTURING THE SAME, AND ELECTRONIC APPARATUS”, the entire content of which is incorporated herein in its entirety by reference.

### TECHNICAL FIELD

The present disclosure relates to a field of semiconductors, and in particular to a semiconductor device having a double-gate structure, a method of manufacturing the semiconductor device having the double-gate structure, and an electronic apparatus including the semiconductor device.

### BACKGROUND

With a continuous miniaturization of semiconductor devices, devices with various structures such as Fin Field-Effect Transistor (FinFET), Multi-Bridge Channel Field-Effect Transistor (MBCFET) have been proposed. However, the room for improvement of these devices in terms of increasing integration density and enhancing device performance due to a limitation of device structure still cannot meet the requirements.

In addition, due to process fluctuations such as photolithography and etching, for a vertical nanosheet or nanowire device such as Metal-Oxide-Semiconductor Field-Effect Transistor (MOSFET), it is difficult to control a thickness or diameter of the nanosheet or nanowire. Moreover, it is difficult to reduce a gate-induced drain leakage (GIDL). For example, for an n-type MOSFET, a negative bias Vgs (<0) may be applied between a gate and a source to reduce a leakage current between the source and a drain. However, if |Vgs| is too large, it may cause GIDL. Therefore, GIDL becomes a limiting factor in reducing leakage.

### SUMMARY

In view of above, the object of the present disclosure is at least partially to provide a semiconductor device having a double-gate structure, a method of manufacturing the semiconductor device having the double-gate structure, and an electronic apparatus including the semiconductor device.

According to an aspect of the present disclosure, a semiconductor device is provided, including: a vertical channel portion on a substrate; source/drain portions respectively located at upper and lower ends of the channel portion relative to the substrate; and a first gate stack on a first side of the channel portion in a first direction lateral to the substrate and a second gate stack on a second side of the channel portion in the first direction, wherein the second side is opposite to the first side. A distance between an upper edge of an end of the first gate stack facing the channel portion in a vertical direction and a corresponding source/drain portion may be less than a distance between a corresponding one of an upper edge and a lower edge of an end of the second gate stack facing the channel portion in the vertical direction and a corresponding source/drain portion, and/or a distance between a lower edge of an end of the first gate stack facing the channel portion in a vertical direction and a corresponding source/drain portion may be less than a distance between a corresponding one of an upper edge and a lower edge of an end of the second gate stack facing the channel portion in the vertical direction and a corresponding source/drain portion.

According to another aspect of the present disclosure, a method of manufacturing a semiconductor device is provided, including: providing a stack of a first material layer, a second material layer, and a third material layer on a substrate, wherein the stack has a first side and a second side opposite to each other in a first direction lateral to the substrate; recessing, on the first side and the second side, a sidewall of the second material layer in the first direction relative to a sidewall of the first material layer and a sidewall of the third material layer, so as to define a first recess portion; further etching, on the first side and the second side, the first material layer, the second material layer, and the third material layer, so as to increase a size of the first recess portion in a vertical direction; forming a channel layer in the first recess portion; forming a first gate stack in the first recess portion in which the channel layer is formed; forming, in the stack, a strip opening extending in a second direction lateral to the substrate, so as to divide the stack into two parts respectively located on the first side and the second side, wherein the second direction intersects with the first direction; and removing the second material layer through the opening, and forming a second gate stack in a space released due to a removal of the second material layer, wherein a size of the first gate stack in the vertical direction is greater than a size of the second gate stack in the vertical direction.

According to another aspect of the present disclosure, an electronic apparatus is provided, including the above-mentioned semiconductor device.

### BRIEF DESCRIPTION OF THE DRAWINGS

The above and other objects, features and advantages of the present disclosure will be more clearly described through the following description of embodiments of the present disclosure with reference to accompanying drawings, in which:

FIGS. 1 to 21(b) show schematic diagrams of some stages in a process of manufacturing a semiconductor device according to an embodiment of the present disclosure, wherein: FIGS. 5(a), 6(a), and 21(a) are top views, and wherein FIG. 5(a) shows positions of line AA′ and line CC′, and FIG. 6(a) shows a position of line BB′; FIGS. 1 to 4, 5(b), 6(b), 7 to 9, 10(a), 10(b), 11 to 14, 15(a), 16, 17(a), 18(a), 20(a) and 21(b) show cross-sectional views taken along line AA′; FIG. 6(c) shows a cross-sectional view taken along line BB′; FIGS. 5(c) and 6(d) show cross-sectional views taken along line CC′; FIGS. 15(b), 17(b), 18(b), 19 and 20(b) show cross-sectional views taken along line DD′ in a corresponding cross-sectional view, and wherein FIG. 15(b) shows a position of line DD′;

FIGS. 22(a) and 22(b) show an energy band diagram of an n-type device according to a comparative example and an energy band diagram of an n-type device according to an embodiment of the present disclosure, respectively;

FIGS. 23(a) to 24(b) show schematic diagrams of some stages in a process of manufacturing a semiconductor device according to another embodiment of the present disclosure, wherein FIGS. 23(a), 23(b), 24(a) and 24(b) show cross-sectional views taken along line AA′;

FIGS. 25 to 26 show schematic diagrams of some stages in a process of manufacturing a semiconductor device according to another embodiment of the present disclosure, wherein FIGS. 25 and 26 show cross-sectional views taken along line AA′;

FIGS. 27(a) and 27(b) show energy band diagrams of n-type devices according to other embodiments of the present disclosure.

Throughout the accompanying drawings, the same or similar reference numbers indicate the same or similar components.

### DETAILED DESCRIPTION OF EMBODIMENTS

Hereinafter, embodiments of the present disclosure will be described with reference to accompanying drawings. However, it should be understood that these descriptions are illustrative and not intended to limit the scope of the present disclosure. Further, in the following, descriptions for known structures and technologies are omitted to avoid obscuring the concept of the present disclosure unnecessarily.

Various structures according to embodiments of the present disclosure are shown in the accompanying drawings. However, they are not drawn to scale, and some features may be enlarged while some features may be omitted for sake of clarity. Shapes, relative sizes and positions of regions and layers shown in the drawings are only illustrative, and deviations may occur due to manufacture tolerances or technique limitations in practice. In addition, those skilled in the art may devise regions/layers of other different shapes, sizes, and relative positions as desired in practice.

In the context of the present disclosure, when a layer/element is recited as being “on” a further layer/element, the layer/element may be provided directly on the further layer/element, or otherwise there may be an intervening layer/element interposed therebetween. Further, if a layer/element is “on” a further layer/element in an orientation, then the layer/element may be “under” the further layer/element when the orientation is reversed.

According to embodiments of the present disclosure, a vertical semiconductor device is provided. The vertical semiconductor device has an active region provided vertically on a substrate (for example, in a direction substantially perpendicular to a surface of the substrate). A channel portion may be a vertical nanosheet or nanowire, such as a curved nanosheet or nanowire with a C-shaped cross-section (such as a cross-section perpendicular to the surface of the substrate). Therefore, such device may be referred to as a C-Channel Field-Effect Transistor (CCFET). As described below; the nanosheet or nanowire may be formed by epitaxial growth, thus the nanosheet or nanowire may be monolithic and have a substantially uniform thickness. The channel portion may have a strain or stress in a vertical direction. Due to such strain, a lattice constant of a material of the channel portion is different from that of the material without strain.

The semiconductor device may further include source/drain portions respectively provided at upper and lower ends of the channel portion. The source/drain portion may be doped to a certain extent. For example, for a p-type device, the source/drain portion may be p-type doped. For an n-type device, the source/drain portion may be n-type doped. The channel portion may be doped to a certain extent to adjust a threshold voltage of the device. Alternatively, the semiconductor device may be a junction free device, and the channel portion and the source/drain portion may have the same conductivity type of doping. Alternatively, the semiconductor device may be a tunneling type device, and the source/drain portions at two ends of the channel portion may have opposite doping types to each other.

The source/drain portion may be provided in a corresponding semiconductor layer. For example, the source/drain portion may be a doped region in the corresponding semiconductor layer. The source/drain portion may be a part of or all of the corresponding semiconductor layer. In a case where the source/drain portion is a part of the corresponding semiconductor layer, a doping concentration interface may exist between the source/drain portion and the rest of the corresponding semiconductor layer. As described below; the source/drain portion may be formed by diffusion doping. In this case, the doping concentration interface may substantially in the vertical direction relative to the substrate.

The channel portion may include a single crystal semiconductor material. The source/drain portions or the semiconductor layers in which they are formed may also include single crystal semiconductor materials. For example, they may all be formed by epitaxial growth.

The semiconductor device may further include a first gate stack and a second gate stack respectively provided on opposite sides of the channel portion in a lateral direction. Edges of the first gate stack and second gate stack on at least one side in the vertical direction may be offset relative to each other. For example, a distance between an upper edge of an end of the first gate stack facing the channel portion in a vertical direction and a corresponding source/drain portion is less than a distance between a corresponding one of an upper edge and a lower edge of an end of the second gate stack facing the channel portion in the vertical direction and a corresponding source/drain portion, and/or a distance between a lower edge of an end of the first gate stack facing the channel portion in a vertical direction and a corresponding source/drain portion is less than a distance between a corresponding one of an upper edge and a lower edge of an end of the second gate stack facing the channel portion in the vertical direction and a corresponding source/drain portion. This helps suppress GIDL.

Such semiconductor device may be manufactured as follows.

According to embodiments, a stack of a first material layer, a second material layer, and a third material layer may be provided on the substrate. The first material layer may define a position of a lower source/drain portion. The second material layer may define a position of the gate stack. The third material layer may define a position of an upper source/drain portion. The first material layer may be provided through the substrate, such as an upper part of the substrate. The second material layer and the third material layer may be sequentially formed on the first material layer by epitaxial growth. Alternatively, the first material layer, the second material layer, and the third material layer may be formed sequentially on the substrate by epitaxial growth.

The semiconductor device may be fabricated based on such stack. The stack may include first and second sides that are opposite to each other in the first direction, as well as third and fourth sides that are opposite to each other in a second direction that intersects with (e.g., perpendicular to) the first direction. For example, the stack may present in a quadrilateral shape such as a rectangle or square in the top view.

A sidewall of the second material layer may be recessed in the first direction relative to sidewalls of the first and third material layers on the first and second sides of the stack, so as to define a first recess portion to define a space for the first gate stack. The first recess portion may have a curved surface recessed towards an inner side of the stack. The channel portion may be formed on a surface of the first recess portion. For example, a first active layer may be formed on an exposed surface of the stack by epitaxial growth. A part of the first active layer located on the surface of the first recess portion may be used as a channel portion (also referred to as a “channel layer”). Devices may be respectively formed based on the first active layer on the sidewalls of the stack on the first and second sides. Therefore, two devices that are opposite to each other may be formed based on a single stack. The first gate stack may be formed in the first recess portion in which the channel layer is formed.

The first recess portion may be formed so that after the formation of the first active layer, a size of the first recess portion in the vertical direction may be different from (for example, greater than) a thickness of the second material layer in the vertical direction. In this way, first and second gate stacks with different gate lengths may be fabricated.

The source/drain portions may be formed in the first and third material layers. For example, the source/drain portions may be formed by doping the first and third material layers. Such doping may be achieved by a solid-phase dopant source layer. When forming the source/drain portions, a first position retaining layer may be formed in the first recess portion in which the channel layer is formed, so as to avoid affecting the channel layer.

An opening may be formed in the stack to separate active regions of the two devices. The opening may extend in the second direction, so as to divide the stack into two parts respectively located on the first and second sides. The two parts of the stack have respective channel layers. The second material layer may be replaced with the second gate stack through this opening.

Before forming the first recess portion on the first and second sides, a second recess portion may be similarly formed on the third and fourth sides, and a second position retaining layer may be formed in the second recess portion. This helps to improve the morphology and size control of the channel layer.

According to embodiments of the present disclosure, the thickness of the nanosheet or nanowire used as the channel portion and the gate length are mainly determined by epitaxial growth, rather than by etching or photolithography, so that good channel size/thickness and gate length control may be achieved.

According to embodiments of the present disclosure, a first gate stack and a second gate stack may be respectively formed on opposite sides of the channel portion. On at least one side in the vertical direction, respective edges of the first gate stack and the second gate stack may be offset relative to each other, so as to suppress GIDL.

The present disclosure may be presented in various forms, some examples of which will be described below. In the following description, a selection of various materials is involved. In the selection of materials, in addition to a function of the material (for example, a semiconductor material may be used to form the active region, a dielectric material may be used to form an electrical isolation), the etching selectivity is also considered. In the following description, the required etching selectivity may or may not be indicated. It should be clear to those skilled in the art that when etching a material layer is mentioned below, if it is not mentioned or shown that other layers are also etched, then the etching may be selective, and the material layer may have an etching selectivity relative to other layers exposed to the same etching recipe.

FIGS. 1 to 21(b) show schematic diagrams of some stages in a process of manufacturing a semiconductor device according to an embodiment of the present disclosure.

As shown in FIG. 1, a substrate 1001 is provided (an upper part of the substrate 1001 may form the first material layer described above). The substrate 1001 may be a substrate in various forms, for example, but not limited to, a bulk semiconductor material substrate such as a bulk Si substrate, a Semiconductor On Insulator (SOI) substrate, a compound semiconductor substrate such as an SiGe substrate, or the like. Hereinafter, the bulk Si substrate will be described by way of example for the convenience of description. Here, a silicon wafer is provided as the substrate 1001.

A well region may be formed in the substrate 1001. If a p-type device is to be formed, the well region may be an n-type well. If an n-type device is to be formed, the well region may be a p-type well. The well region may be formed, for example, by injecting a dopant of a corresponding conductivity type (a p-type dopant such as B or In, or an n-type dopant such as As or P) into the substrate 1001 and subsequently undergoing thermal annealing. There are multiple ways to provide such well region in the art, which will not be repeated here.

A second material layer 1003 and a third material layer 1005 may be formed on the substrate 1001 by epitaxial growth, for example. The second material layer 1003 may be used to define the position of the gate stack, with a thickness ranging from about 20 nm to 50 nm. The third material layer 1005 may be used to define the position of the upper source/drain portion, with a thickness ranging from about 20 nm to 200 nm.

Adjacent layers among the substrate 1001 and layers formed on the substrate 1001 may have etching selectivity relative to each other. For example, in a case that the substrate 1001 is the silicon wafer, the second material layer 1003 may include SiGe (for example, an atom percentage of Ge is in a range of about 10% to 30%), and the third material layer 1005 may include Si.

Lateral directions x and z, and a vertical direction y are schematically shown in FIG. 1. The x-direction and the z-direction may be parallel to a top surface of the substrate 1001 and perpendicular to each other. The y-direction may be substantially perpendicular to the top surface of the substrate 1001. Since there is no constraint at a top, a stress in the second material layer 1003 in the y-direction may be released. The x-direction may be the first direction described above, and the z-direction may be the second direction described above.

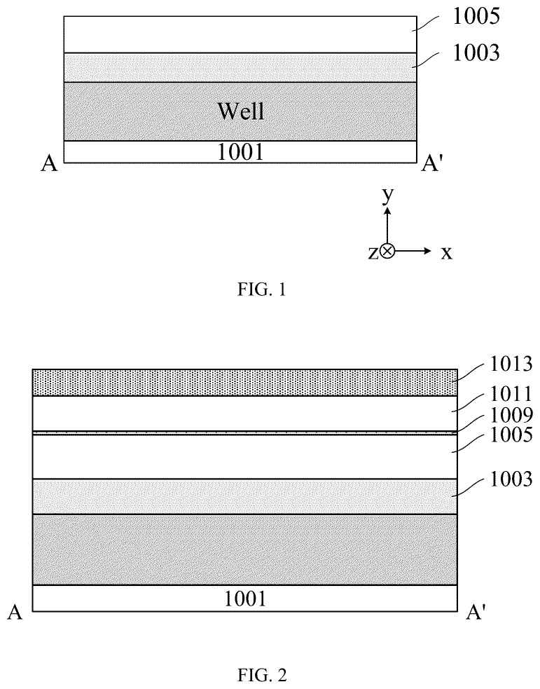

According to embodiments, a spacer pattern transfer technology is used in the following patterning process. To form a spacer, a mandrel pattern may be formed. For example, as shown in FIG. 2, a layer 1011 used for the mandrel pattern may be formed on the third material layer 1005, for example, by deposition. For example, the layer 1011 used for the mandrel pattern may include amorphous silicon or polycrystalline silicon, with a thickness ranging from about 50 nm to 150 nm. In addition, for better etching control, an etching stop layer 1009 may be formed, for example, by deposition. For example, the etching stop layer 1009 may include an oxide (such as silicon oxide) with a thickness ranging from about 1 nm to 10 nm.

A hard mask layer 1013 may be formed on the layer 1011 used for the mandrel pattern, for example, by deposition. For example, the hard mask layer 1013 may include a nitride (such as silicon nitride) with a thickness ranging from about 30 nm to 100 nm.

The layer 1011 used for the mandrel pattern may be patterned as the mandrel pattern.

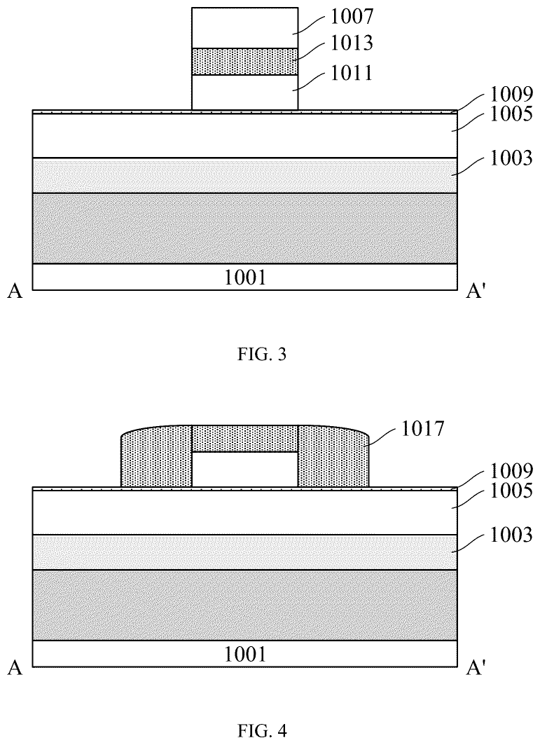

For example, as shown in FIG. 3, a photoresist 1007 may be formed on the hard mask layer 1013 and patterned as a strip extending along the z-direction by photolithography. By using the photoresist 1007 as an etching mask, selectively etching may be performed on the hard mask layer 1013 and the layer 1011 used for the mandrel pattern sequentially, for example, by reactive ion etching (RIE), so as to transfer a pattern of the photoresist to the hard mask layer 1013 and the layer 1011 used for the mandrel pattern. RIE may be performed in a substantially vertical direction and may stop at the etching stop layer 1009. Afterwards, the photoresist 1007 may be removed.

As shown in FIG. 4, a spacer 1017 may be formed on opposite sidewalls of the mandrel pattern 1011 in the x-direction. For example, a layer of nitride with a thickness ranging from about 10 nm to 100 nm may be deposited in a substantially conformal manner, and then anisotropic etching such as RIE (which may be performed in a substantially vertical direction and may stop at the etching stop layer 1009) may be performed on the deposited nitride layer in the vertical direction, so as to remove a lateral extension part of the deposited nitride layer and leave a vertical extension part of the deposited nitride layer to obtain the spacer 1017. The spacer 1017 may then be used to define a position of the active region of the device.

The mandrel pattern formed as described above and the spacer 1017 formed on the sidewalls of the mandrel pattern extend in the z-direction. A range of the mandrel pattern and the spacer 1017 in the z-direction may be defined, so as to define a range of the active region of the device in the z-direction.

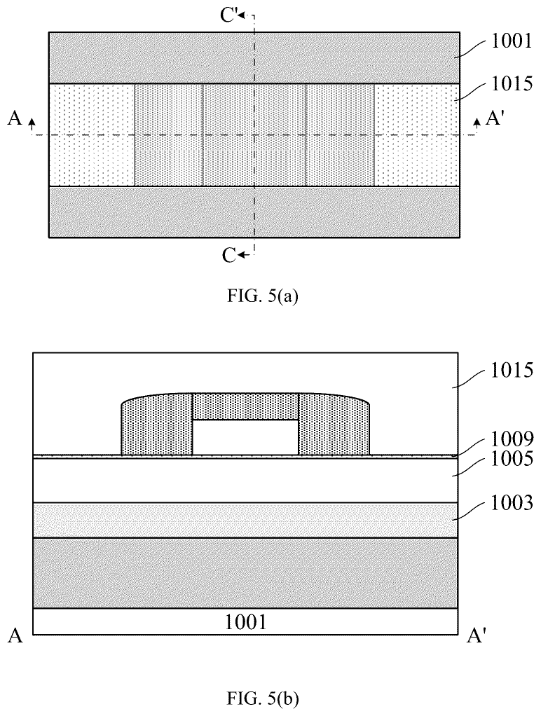

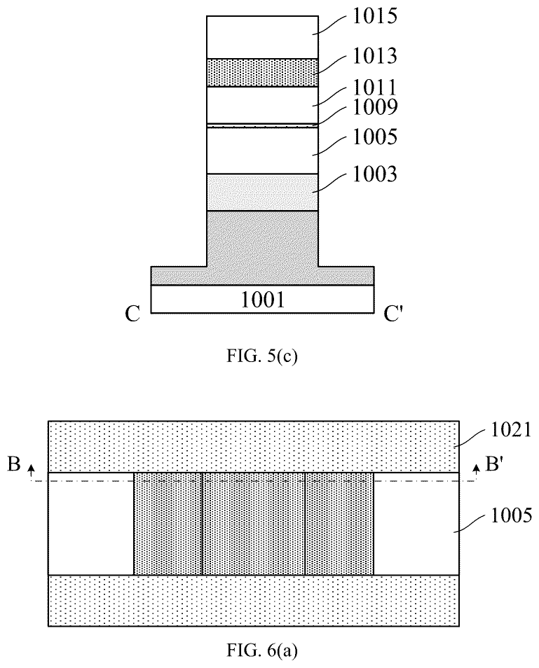

As shown in FIGS. 5(a) to 5(c), a photoresist 1015 may be formed on a structure shown in FIG. 4 and patterned as, for example, a strip that extends in the x-direction and occupies a certain range in the z-direction, by photolithography. By using the photoresist 1015 as an etching mask, selectively etching may be performed on the underlying layers in sequence, for example, by RIE. Etching may be performed into the substrate 1001, especially in the well region, so as to form a trench in the substrate 1001. Isolation such as shallow trench isolation (STI) may then be formed in the formed trench. Afterwards, the photoresist 1015 may be removed.

As shown in FIG. 5(c), a sidewall of the second material layer 1003 in the z-direction is currently exposed.

According to embodiments of the present disclosure, in order to avoid affecting the sidewall of the second material layer 1003 in the z-direction when processing (forming a recess portion and forming a channel layer in the formed recess portion as described below) the sidewall of the second material layer 1003 in the x-direction, the sidewall of the second material layer 1003 in the z-direction may be shielded.

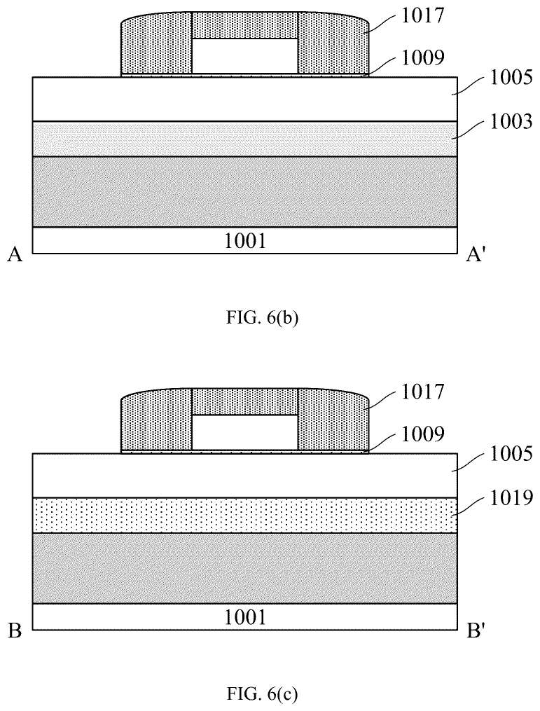

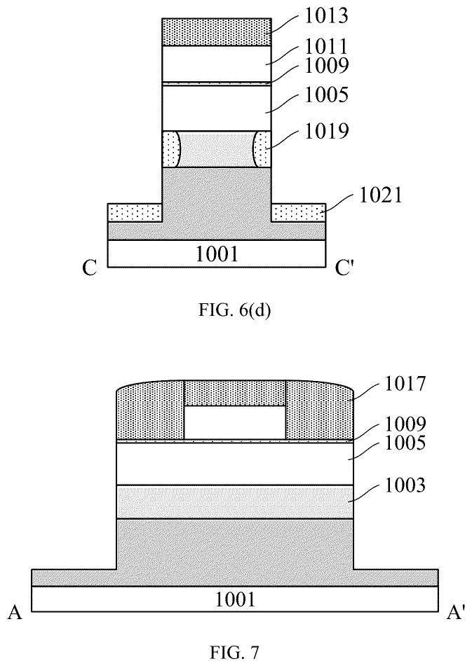

For example, as shown in FIGS. 6(a) to 6(d), the second material layer 1003 may be selectively etched so that the sidewall of the second material layer 1003 in the z-direction is relatively recessed, so as to form a recess portion. To better control the amount of etching, atomic layer etching (ALE) may be used. For example, the amount of etching may be in a range of about 5 nm to 20 nm. Depending on the etching characteristics, such as the etching selectivity of the second material layer 1003 relative to the substrate 1001 and the third material layer 1005, the sidewall of the second material layer 1003 may have different shapes after etching. As shown in FIG. 6(d), the sidewall of the second material layer 1003 after etching has an inward-recessed C-shape. However, the present disclosure is not limited to this. For example, when the etching selectivity is good, the sidewall of the second material layer 1003 after etching may be substantially vertical. Here, etching may be isotropic, especially when a large etching amount is required. The recess portion formed in this way may be filled with a dielectric material. Such filling may be performed by deposition followed by etching back. For example, the dielectric material such as oxide, which is sufficient to fill the recess portion, may be deposited on the substrate, and then the deposited dielectric material may be etched back by RIE. In this way, the dielectric material may be retained in the recess portion to form a first position retaining layer 1019. Before etching back, a planarization processing such as chemical mechanical polishing (CMP) may be performed on the deposited dielectric material (CMP may stop at the hard mask layer 1013).

According to embodiments of the present disclosure, a certain thickness of the dielectric material may be left on the substrate 1001 during etching back, so as to form a protective layer 1021. Here, the protective layer 1021 may be located in the trench of the substrate 1001, and a top surface of the protective layer 1021 is lower than the top surface of the substrate 1001. In addition, during the etching back process, an exposed part of the etching stop layer 1009 (also an oxide in this example) may also be etched.

The protective layer 1021 may protect the surface of the substrate 1001 in the following processing. For example, in this example, a range of the active region in the z-direction is defined. Then, a range of the active region in the x-direction may be defined. The protective layer 1021 may also avoid affecting the surface (see FIG. 5(c)) of the substrate currently exposed in the trench when defining the range in the x-direction. In addition, when different types of well regions are formed in the substrate 1001, the protective layer 1021 may protect a p-n junction between different types of well regions from being damaged by etching.

As shown in FIG. 7, the third material layer 1005, the second material layer 1003, and the upper part (the first material layer) of the substrate 1001 may be patterned as a ridge structure (in fact, a range of the ridge structure in the z-direction has been defined by the above processing) by using the hard mask layer 1013 and the spacer 1017. For example, by using the hard mask layer 1013 and the spacer 1017 as an etching mask, selectively etching may be performed on various layers in sequence by RIE, so as to transfer the pattern to an underlying layer. Accordingly, the upper part of the substrate 1001, the second material layer 1003, and the third material layer 1005 may form the ridge structure. As described above, due to the presence of the protective layer 1021, etching may not affect parts of the substrate 1001 on two sides of the ridge structure in the z-direction.

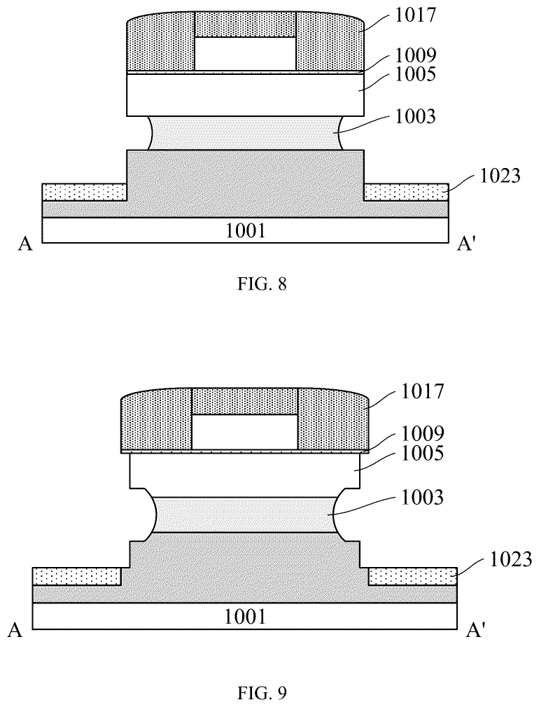

Etching may enter the well region of the substrate 1001. A degree of etching entering the substrate 1001 may be substantially identical or similar to a degree of etching entering the substrate 1001 described above in conjunction with FIGS. 5(a) to 5(c). Similarly, a trench is formed in the substrate 1001. A protective layer (see 1023 in FIG. 8) may also be formed in the trench, for example, by deposition, planarization followed by etching back the oxide. This protective layer 1023 surrounds a periphery of the ridge structure along with the previous protective layer 1021. In this way, similar processing conditions may be achieved around the ridge structure, that is, trenches are formed in the substrate 1001, and protective layers 1021 and 1023 are formed in the trenches.

A space used for the gate stack may be left at two ends of the second material layer in the x-direction. For example, as shown in FIG. 8, the second material layer 1003 may be selectively etched, so that the sidewall of the second material layer 1003 in the x-direction is relatively recessed to form a recess portion (which may define the space used for the gate stack). To better control the amount of etching, ALE may be used. For example, the amount of etching may be in a range of about 10 nm to 40 nm. As described above, the sidewall of the second material layer 1003 after etching may present the inward-recessed C-shape. Here, etching may be isotropic, especially when a large etching amount is required. Usually, the C-shaped sidewall of the second material layer 1003 have a larger curvature at the upper and lower ends, while a smaller curvature at the waist or middle. Of course, the sidewall of the second material layer 1003 may also be substantially vertical.

A first active layer may be formed on the sidewall of the ridge structure to subsequently define the channel portion. In order to offset respective edges of gate stacks on at least one side in the vertical direction relative to each other when subsequently forming the gate stacks on left and right sides of the channel portion, as shown in FIG. 9, the ridge structure (specifically, exposed surfaces of the first material layer, second material layer and third material layer) may be etched back, so that an outer sidewall of the ridge structure may be recessed in the lateral direction relative to an outer sidewall of the spacer 1017. To control the etching depth, ALE may be used. The etching depth may be in a range of about 10 nm to 25 nm, for example.

An etchant may be selected so that the etching depth of the first material layer in the vertical direction may be substantially identical to the etching depth of the third material layer in the vertical direction.

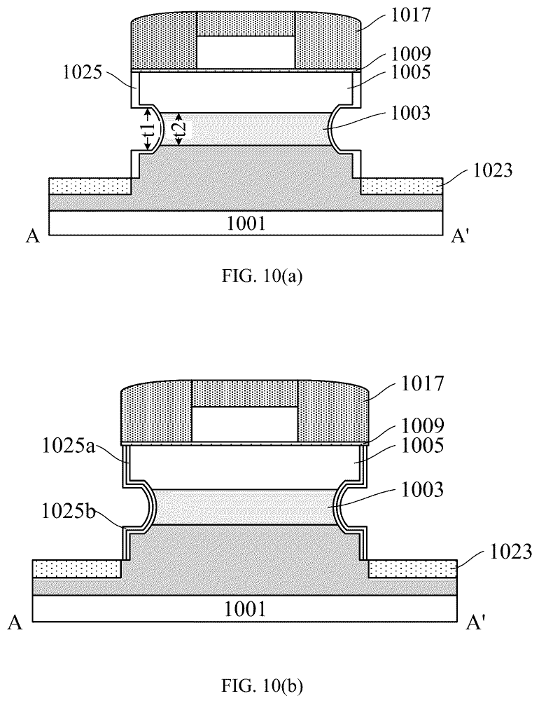

Then, as shown in FIG. 10(a), a first active layer 1025 may be formed on the sidewall of the ridge structure, for example, by selective epitaxial growth. Due to selective epitaxial growth, the first active layer 1025 may not be formed on the surface of the first position retaining layer 1019. The first active layer 1025 may then define the channel portion, with a thickness in a range of, for example, about 3 nm to 15 nm. As the channel portion (although it may be C-shaped) mainly extends in the vertical direction, the first active layer 1025 (especially a part of the first active layer 1025 on the sidewall of the second material layer) may also be referred to as the (vertical) channel layer. According to embodiments of the present disclosure, a thickness of the first active layer 1025 (subsequently used as the channel portion) may be determined by an epitaxial growth process, so as to better control the thickness of the channel portion. The first active layer 1025 may be doped in situ during epitaxial growth to adjust the threshold voltage of the device.

As shown in FIG. 10(a), a part of the first active layer 1025 on the sidewalls of the first and third material layers is shown to be relatively thick, so that the sidewall of the first active layer 1025 is substantially flush with the sidewall of the spacer 1017, which is only for the convenience of the illustration. The first active layer 1025 grown may have a substantially uniform thickness. In addition, a sidewall of the part of the first active layer 1025 on the sidewalls of the first and third material layers may be recessed relative to the sidewall of the spacer 1017, or may even protrude.

The above-mentioned etching back of the ridge structure may etch the upper and lower ends of the recess portion upwards and downwards, respectively, so that after the growth of the first active layer 1025, a height t1 (corresponding to the gate length of the subsequently formed first gate stack) of the recess portion may be different from a thickness t2 (corresponding to the gate length of the subsequently formed second gate stack) of the second material layer 1003, especially in this example, t1 may be greater than t2. In this way, the first and second gate stacks respectively formed on left and right sides of the first active layer 1025 may have different gate lengths. An etching recipe may be selected so that an amount of upward etching on the upper end of the recess portion is substantially identical to an amount of downward etching on the lower end of the recess portion. Therefore, the recess portion with increased height may be self-aligned with the second material layer 1003, so that the first and second gate stacks formed on left and right sides of the first active layer 1025 may be self-aligned with each other.

The first active layer 1025 may include various semiconductor materials, such as an elemental semiconductor material such as Si, Ge, etc., or a compound semiconductor material such as SiGe, InP, GaAs, InGaAs, etc. The material of the first active layer 1025 may be appropriately selected based on the performance requirements of the device in the design. In this example, the first active layer 1025 may include Si.

In an example shown in FIG. 10(a), the first active layers 1025 on opposite sides of the ridge structure in the x-direction may have substantially the same characteristics (such as material, size, doping characteristics, etc.), and may be symmetrically provided on opposite sides of the second material layer. However, the present disclosure is not limited to this. As described below; two devices that are opposite to each other may be formed through a single ridge structure. According to the performance requirements of the design for these two devices, the first active layers 1025 on opposite sides of the ridge structure may have different characteristics, such as different in at least one aspect of thickness, material, and doping characteristics. This may be achieved by growing the first active layer in one device region while shielding another device region.

According to other embodiments of the present disclosure, in order to generate a stress in the channel portion to enhance the device performance, a lattice constant of the material of the first active layer 1025 without strain may be different from a lattice constant of the material of the second material layer 1003 without strain. For example, when the lattice constant of the material of the second material layer 1003 without strain is greater than the lattice constant of the material of the first active layer 1025 without strain, the first active layer 1025 may have a tensile stress (for example, for the n-type device). When the lattice constant of the material of the second material layer 1003 without strain is less than the lattice constant of the material of the first active layer 1025 without strain, the first active layer 1025 may have a compressive stress (for example, for the p-type device).

In a case that the first active layer 1025 includes Si, as the second material layer 1003 (in this example, SiGe) is relaxed in the y-direction as described above, the first active layer 1025 may have a tensile stress substantially in the x-direction. According to other embodiments of the present disclosure, different types and/or different levels of stress may also be achieved through different materials or combinations of materials.

In an example, as shown in FIG. 10(b), an etching stop layer 1025a and a first active layer 1025b may be sequentially formed on the sidewall of the ridge structure by selective epitaxial growth, for example. The etching stop layer 1025a may define an etching stop position during subsequent etching of the second material layer 1003 (this is because in this example, both the first active layer 1025b and the second material layer 1003 include SiGe, if the etching stop layer 1025a is not provided, the first active layer 1025b may be affected when etching the second material layer 1003), a thickness of the etching stop layer 1025a is in a range of, for example, about 1 nm to 5 nm. The first active layer 1025b, as described above, may then define the channel portion, with a thickness in a range of, for example, about 3 nm to 15 nm. In this example, the etching stop layer 1025a may include Si, and the first active layer 1025b may include SiGe. To achieve the compressive stress, the atomic percentage of Ge in the first active layer 1025b may be greater than the atomic percentage of Ge in the second material layer 1003.

Different semiconductor materials, such as III-V compound semiconductor materials, may be grown to achieve a desired strain or stress.

Hereinafter, for convenience, the case in FIG. 10(a) is still described as an example.

The first gate stack may be subsequently formed in the recess portion. To prevent the subsequent processing from leaving an unnecessary material in the recess portion or affecting the first active layer 1025, as shown in FIG. 11, a second position retaining layer 1027 may be formed in the recess portion. Similarly, the second position retaining layer 1027 may be formed by deposition followed by etching back, and may include a material with etching selectivity relative to the first position retaining layer 1019, such as SiC.

In FIG. 11 and subsequent drawings, for the convenience of the illustration, a part of the first active layer 1025 adjacent to the third material layer 1005 is shown as integrated with the third material layer 1005.

Afterwards, source/drain doping may be performed.

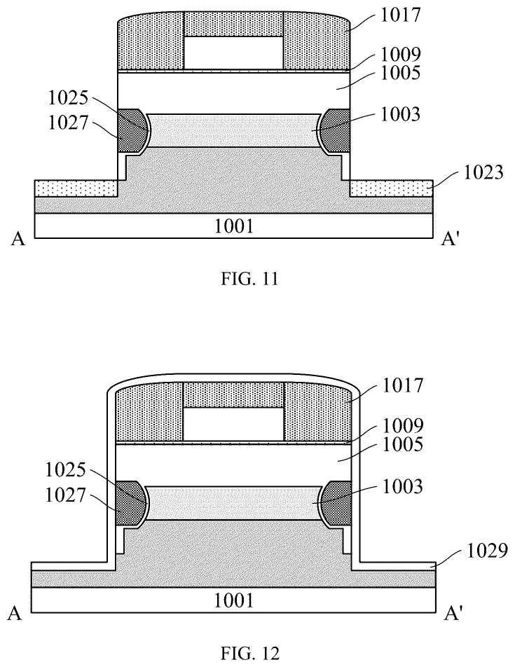

As shown in FIG. 12, a solid-phase dopant source layer 1029 may be formed on the structure shown in FIG. 11, for example, by deposition. The solid-phase dopant source layer 1029 may be formed in a substantially conformal manner. For example, the solid-phase dopant source layer 1029 may be an oxide containing a dopant, with a thickness in a range of about 1 nm to 5 nm. The dopant contained in the solid-phase dopant source layer 1029 may be used to dope the source/drain portion (and optionally, the exposed surface of the substrate 1001), thus the dopant may have the same conductivity type as the desired source/drain portion. For example, for the p-type device, the solid-phase dopant source layer 1029 may contain a p-type dopant such as B or In. For the n-type device, the solid-phase dopant source layer 1029 may contain an n-type dopant such as P or As. A concentration of the dopant in the solid-phase dopant source layer 1029 may be in a range of about 0.1% to 5%.

In this example, before forming the solid-phase dopant source layer 1029, the protective layers 1021 and 1023 may be selectively etched by, for example, RIE, so as to expose the surface of the substrate 1001. In this way, the exposed surface of the substrate 1001 may also be doped to form respective contact regions of the lower source/drain portions S/D of the two devices.

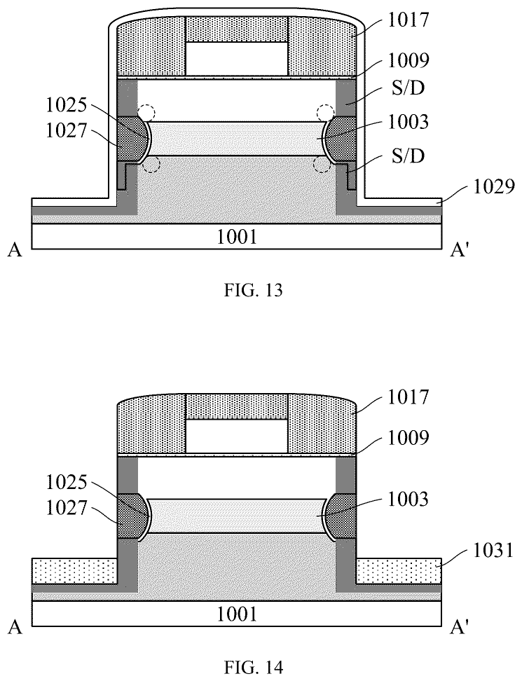

The dopant in the solid-phase dopant source layer 1029 may be driven into the first and third material layers through annealing processing, so as to form source/drain portions S/D (and optionally; the dopant may be driven into the exposed surface of the substrate 1001 to form respective contact regions of the lower source/drain portions S/D of the two devices), as shown in FIG. 13. Afterwards, the solid-phase dopant source layer 1029 may be removed.

As the first and third material layers may have the same material and the solid-phase dopant source layer 1029 may be formed on surfaces of the first and third material layers in a substantially conformal manner, degrees of driving the dopant from the solid-phase dopant source layer 1029 into the first and third material layers may be substantially the same. Therefore, (doping concentration) interfaces of the source/drain portions S/D (and inner parts of the first and third material layers) may be substantially parallel to the sidewalls of the first and third material layers, that is, the interfaces of the source/drain portions S/D may be aligned with each other in the vertical direction.

In addition, the degree of driving the dopant in the lateral direction may be controlled, so that parts (as shown by the dashed circles in the figure) of the first and third material layers close to the subsequently formed second gate stack may be low doped (relative to the source/drain portion) or substantially unintentionally doped (for example, the dopant from the solid-phase dopant source layer 1029 may substantially not enter such parts). This helps to prevent band-to-band tunneling caused by the gate voltage, and/or reduce GIDL.

The part of the first active layer 1025 on the sidewall of the first material layer currently has substantially the same doping (forming the lower source/drain portion S/D) as the part of the first material layer around the first active layer 1025. Therefore, for the convenience of illustration, the interface between the part of the first active layer 1025 on the sidewall of the first material layer and the part of the first material layer around the first active layer 1025 will not be shown in the following drawings.

In this example, the first material layer is provided by the upper part of the substrate 1001. However, the present disclosure is not limited to this. For example, the first material layer may also be an epitaxial layer on the substrate 1001. In this case, the first and third material layers may be doped in situ during epitaxy, rather than using a solid-phase dopant source layer for doping.

An isolation layer 1031 such as shallow trench isolation (STI) may be formed in the trench around the ridge structure, as shown in FIG. 14. The method of forming the isolation layer may be similar to the method of forming the protective layers 1021 and 1023 mentioned above, which will not be repeated here.

So far, the first position retaining layer 1019 and the second position retaining layer 1027 (on the outer side), as well as the second material layer 1003 (on the inner side) surround a part of the first active layer 1025. This part of the first active layer 1025 may be used as the channel portion. The channel portion may be a curved nanosheet in a C-shape (when the nanosheet is narrow; for example, when a size of the channel portion in the z-direction, i.e. a direction perpendicular to the paper surface in FIG. 14, is relatively small, the channel portion may become a nanowire). Due to the high etching selectivity of the second material layer 1003 (SiGe) relative to the first active layer 1025 (Si) during etching, the thickness (in the case of nanowires, thickness or diameter) of the channel portion is substantially determined by the selective growth process of the first active layer 1025. This has significant advantages over using only etching or photolithography methods to determine the thickness, as epitaxial growth process has much better process control compared to etching or photolithography. Therefore, the control of stress is also better.

The gate stacks may be formed on two sides of the channel portion.

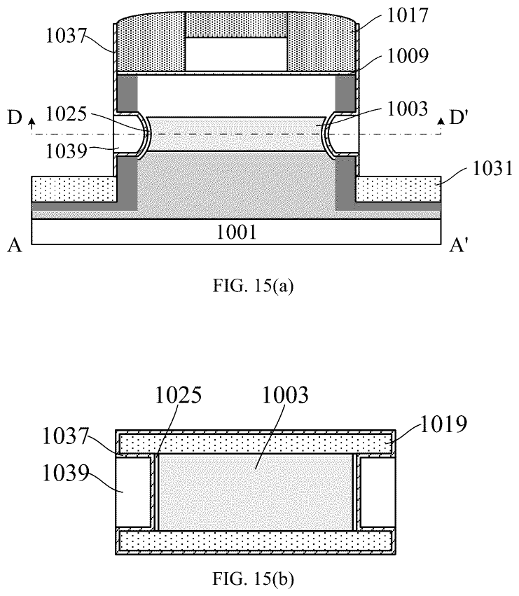

For example, as shown in FIGS. 15(a) and 15(b), the second position retaining layer 1027 (in this example, SiC) may be removed by selective etching. The first position retaining layer 1019 (in this example, oxide) may be retained. Thereby, a space occupied by the second position retaining layer 1027 may be released, and a part of the first active layer 1025 may be exposed. The first gate stack may be formed in the released space. For example, a gate dielectric layer 1037 may be formed in a substantially conformal manner by deposition, and a gate conductor layer 1039 may be formed on the gate dielectric layer 1037. By deposition followed by etching back, the gate conductor layer 1039 may substantially occupy the space where the second position retaining layer 1027 is previous located. Anisotropic etching such as RIE in the vertical direction may further be performed on the gate dielectric layer 1037, so as to expose the hard mask layer 1013 for subsequent processing.

For example, the gate dielectric layer 1037 may include a high k gate dielectric such as HfO₂, with a thickness in a range of about 2 nm to 10 nm. Before forming the high k gate dielectric, an interface layer may be formed, such as an oxide formed by an oxidation process or deposition such as atomic layer deposition (ALD), with a thickness in a range of about 0.3 nm to 1.5 nm. The gate conductor layer 1039 may include a work function regulating metal such as TiN, TaN, TiAlC, and a gate conductive metal such as W.

In addition, when removing the second position retaining layer 1027, the first active layer 1025 is retained on the inner side by the second material layer 1003, so as to suppress the release of stress therein.

Next, the inner side of the channel portion may be processed. As shown in FIG. 15(b), when processing the inner side of the channel portion, the first active layer 1025 is retained on the outer side by the gate dielectric layer 1037 and the gate conductor layer 1039, so as to suppress the release of stress therein.

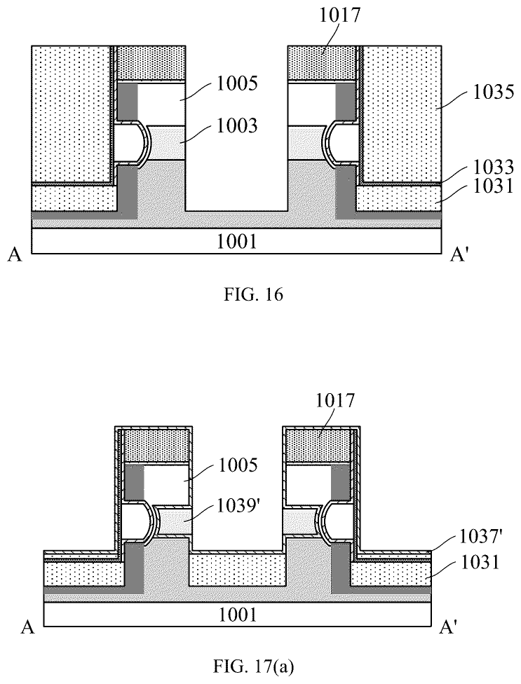

In order to provide an etching stop layer and avoid affecting the first gate stack already formed on the outer side during processing on the inner side, as shown in FIG. 16, an etching stop layer or a protective layer 1033 may be formed on the isolation layer 1031. The etching stop layer or protective layer 1033 may be formed in a substantially conformal manner and may include a material that has a required etching selectivity (for example, relative to the gate stack, the isolation layer, the first to third material layers, etc., which may be understood based on subsequent selective etching operations), such as SiC.

A dielectric material 1035, such as an oxide, may be formed on the etching stop layer or protective layer 1033 by deposition. The dielectric material 1035 helps to open a processing channel to the inner side. For example, a planarization processing such as CMP may be performed to remove the hard mask layer 1013, so as to expose the mandrel pattern 1011. During the planarization processing, a height of the spacer 1017 may be reduced. Then, the mandrel pattern 1011 may be removed by selective etching, such as wet etching using TMAH solution or dry etching using RIE. In this way, a pair of the spacers 1017 extending opposite to each other is left on the ridge structure (the height decreases, and the top morphology may also change).

By using the spacer 1017 and the dielectric material 1035 as the etching mask, the etching stop layer 1009, the third material layer 1005, the second material layer 1003, and the upper part of the substrate 1001 may be selectively etched in sequence, for example, by RIE. Etching may be performed into the well region of the substrate 1001. In this way, within the space surrounded by the isolation layer 1031, a pair of stacks corresponding to the spacers 1017 is formed by the third material layer 1005, the second material layer 1003, and the upper part of the substrate 1001 to define the active regions.

The formation of the stack used to define the active region is not limited to the spacer pattern transfer technology, but may also be performed through photolithography by using the photoresist.

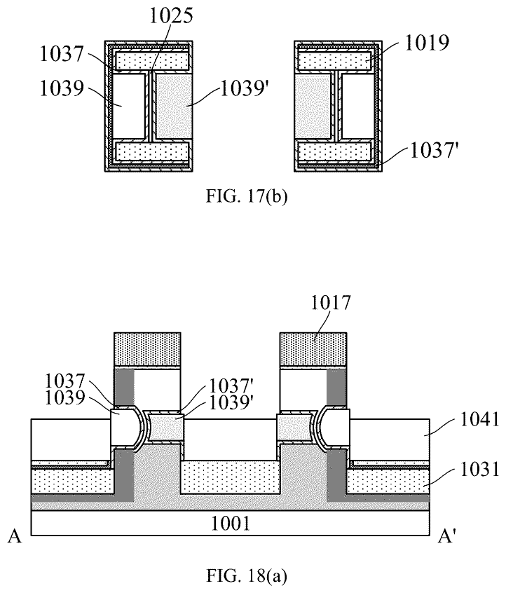

Then, as shown in FIGS. 17(a) and 17(b), the second material layer 1003 (SiGe in this example) may be removed by selective etching relative to the first active layer 1025, the substrate 1001, and the third material layer 1005 (all Si in this example). Thus, the inner side of the channel portion is exposed. At this point, the channel portion is retained by the first gate stack on the outer side, so as to suppress the release of stress therein.

In a case shown in FIG. 10(b), selective etching of the second material layer 1003 may be stopped at the etching stop layer 1025a, and further the etching stop layer 1025a may be removed to expose the first active layer 1025b. Alternatively, the etching stop layer 1025a may also be retained, as the etching stop layer 1025a of Si helps improve the gate-dielectric interface characteristics.

Similarly, a second gate stack may be formed on the inner side.

Before forming the second gate stack, an isolation layer may be formed on the inner side. For example, as shown in FIGS. 17(a) and 17(b), the isolation layer may be formed on the inner side by deposition (and planarization) followed by etching back. For example, the isolation layer may include an oxide and thus is shown as 1031 along with the previous isolation layer 1031 and the dielectric material 1035 (also etched back together). A top surface of the isolation layer 1031 may be lower than the top surface of the first material layer (i.e., the top surface of the substrate 1001) or the bottom surface of the second material layer. A gate dielectric layer 1037′ may be formed by deposition in a substantially conformal manner, and a gate conductor layer 1039′ may be formed on the gate dielectric layer 1037′. By deposition followed by etching back, the gate conductor layer 1039′ may substantially occupy the space previously occupied by the second material layer 1003.

Similarly, the gate dielectric layer 1037′ may also include a high k gate dielectric such as HfO₂, with a thickness in a range of about 2 nm to 10 nm. Before forming the high k gate dielectric, an interface layer may be formed, such as an oxide with a thickness in a range of about 0.3 nm to 1.5 nm.

In order to optimize the device performance, the gate dielectric layer 1037′ may have different performance parameters (such as material, thickness, etc.) from the gate dielectric layer 1037.

Similarly, the gate conductor layer 1039′ may include a work function regulating metal such as TiN, TaN and TiAlC, and a gate conductive metal such as W. To optimize the device performance, the gate conductor layer 1039′ may have different performance parameters (such as material, effective work function, etc.) from the gate conductor layer 1039. For example, the gate conductor layer 1039 and the gate conductor layer 1039′ may include metal elements that are different from each other.

According to embodiments of the present disclosure, a threshold voltage (Vt) caused by the first gate stack (1037/1039) and a threshold voltage (Vt) caused by the second gate stack (1037′/1039′) may be different from each other. For example, for the n-type device, a Vt of a part of the channel portion adjacent to the first gate stack may be lower than a Vt of a part of the channel portion adjacent to the second gate stack. For the p-type device, a Vt of the part of the channel portion adjacent to the first gate stack may be higher than a Vt of the part of the channel portion adjacent to the second gate stack.

According to embodiments of the present disclosure, an effective work function of the first gate stack (1037/1039) and an effective work function of the second gate stack (1037′/1039′) may be different from each other. For example, for the n-type device, the effective work function of the first gate stack may be less than the effective work function of the second gate stack (for example, the second gate stack includes Ti, and the first gate stack includes Al). For the p-type device, the effective work function of the first gate stack may be greater than the effective work function of the second gate stack (for example, the second gate stack includes Al, and the first gate stack includes Ti).

At this point, the manufacturing of the device has been substantially completed. As shown in FIGS. 17(a) and 17(b), the device includes a vertical channel portion that may be in a curve shape such as a C shape. The first gate stack with a first gate length (t1) may be formed on one side of the channel portion in the lateral direction (such as the x-direction). The second gate stack with a second gate length (t2) may be formed on one side of the channel portion in the lateral direction (such as the x-direction). As mentioned above, the first gate length may be different from the second gate length, especially the first gate length may be greater than the second gate length. Therefore, a distance between the edge of the first gate stack in the vertical direction (such as the y-direction) and the source/drain portion may be less than a distance between the edge of the second gate stack in the vertical direction (such as the y-direction) and the source/drain portion. The first and second gate stacks may be self-aligned with each other, for example, respective centers of the first and second gate stacks in the vertical direction (such as the y-direction) may be aligned in the lateral direction (such as the x-direction).

The first and second gate stacks are electrically isolated from each other. The first and second gate stacks may be electrically connected to each other through an interconnection structure formed in a back end of the line (BEOL).

According to another embodiment of the present disclosure, the first and second gate stacks may be electrically connected in the following way to save area.

In the states shown in FIGS. 17(a) and 17(b), the gate conductor layer 1039 formed on the outer side is surrounded by other layers (such as the gate dielectric layers 1037 and 1037′, the protective layer 1033, and the first position retaining layer 1019). In order to enable the gate conductor layers on inner and outer sides of the channel portion to be electrically connected to each other, at least part of the sidewall of the gate conductor layer 1039 (especially in the z-direction) may be exposed.

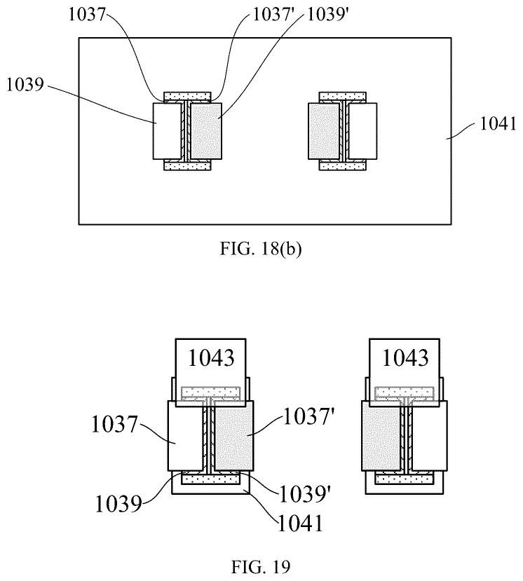

To this end, as shown in FIGS. 18(a) and 18(b), selective etching may be performed on the gate dielectric layer 1037′, the protective layer 1033, and the gate dielectric layer 1037 in sequence, such as by RIE. Therefore, the first position retaining layer 1019 may be exposed. The first position retaining layer 1019 may be selectively etched to release a space occupied by a part of the first position retaining layer 1019. In the released space, a conductor may then be formed to electrically connect the first and second gate stacks. To control the etching amount of the first position retaining layer 1019, ALE may be used. The first position retaining layer 1019 left may protect the channel portion (especially an end of the channel portion in the z-direction), and thus may be referred to as the protective layer. Afterwards, selective etching such as RIE may be further performed on the gate dielectric layer 1037′ and the gate dielectric layer 1037 to expose at least part of the sidewalls of the gate conductor layers 1039 and 1039′ in the z-direction.

A conductive layer 1041 may be formed on the isolation layer 1031 by deposition. A planarization processing such as CMP may be performed on the conductive layer 1041, and CMP may stop at the spacer 1017. Then, the conductive layer 1041 may be etched back so that a top surface of the conductive layer 1041 is lower than the bottom surface of the upper source/drain portion (or the top surface of the second material layer or the bottom surface of the third material layer), so as to avoid a short circuit between the conductive layer 1041 and the source/drain portion. The space released due to selective etching of the first position retaining layer 1019 may be filled with the conductive layer 1041. The gate conductor layers 1039 and 1039′ may be electrically connected to each other through the conductive layer 1041.

Currently, two devices are electrically connected to each other due to the conductive layer 1041. According to the device design, the conductive layer 1041 may be disconnected between two devices through, for example, photolithography, while a landing pad of a gate contact portion may also be patterned.

As shown in FIG. 19, a photoresist 1043 may be formed and patterned to shield a region where the landing pad of the gate contact portion is to be formed and expose other regions. Here, the photoresist 1043 may cover a part of the conductive layer 1041 exposed by the spacer 1017 on a side (the upper side in FIG. 19) of the spacer 1017 in the z-direction, so that the conductive layer 1041 may continuously extend between the gate conductor layers 1039 and 1039′ on inner and outer sides of the channel portion on that side.

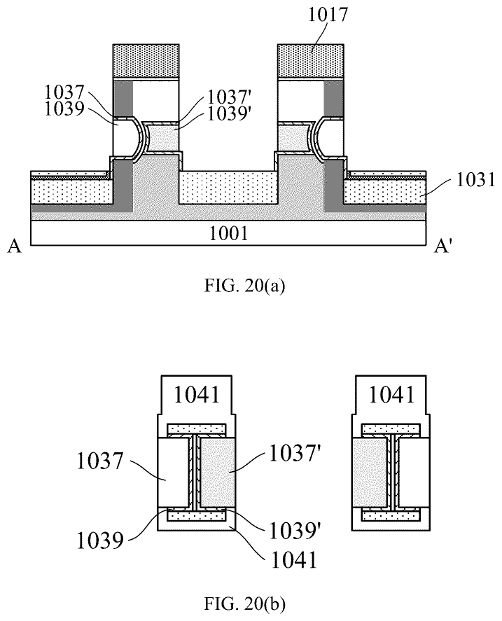

Then, as shown in FIGS. 20(a) and 20(b), selective etching such as RIE may be performed on the conductive layer 1041 by using the photoresist 1043 (and the spacer 1017) as a mask. Afterwards, the photoresist 1043 may be removed. Here, the gate conductor layers 1039 and 1039′ may also be etched by an etchant used to etch the conductive layer 1041.

Therefore, the gate conductor layers 1039 and 1039′, as well as the conductive layer 1041 are substantially left and self-aligned below the spacer 1017, except for a part of the conductive layer 1041 protruding on one side (the upper side in FIG. 20(b)) of the spacer 1017 to serve as a landing pad. The conductive layer 1041 is separated between two opposite devices respectively located below the opposite spacers 1017.

As shown in FIG. 20(b), the first gate stack (1037/1039) is on one side of the channel portion in the x-direction; the second gate stack (1037′/1039′) is on the other side of the channel portion in the x-direction. The first and second gate stacks may be electrically connected to each other through the conductive layer 1041. The two ends of the channel portion in the z-direction are covered by the first position retaining layer 1019 (i.e., the protective layer).

In this example, respective landing pads of the two devices are located on the same side (the upper side in FIG. 20(b)) of the opposite spacers 1017. However, the present disclosure is not limited to this. For example, respective landing pads of the two devices may be located in different sides.

Next, various contact portions and interconnection structures may be fabricated.

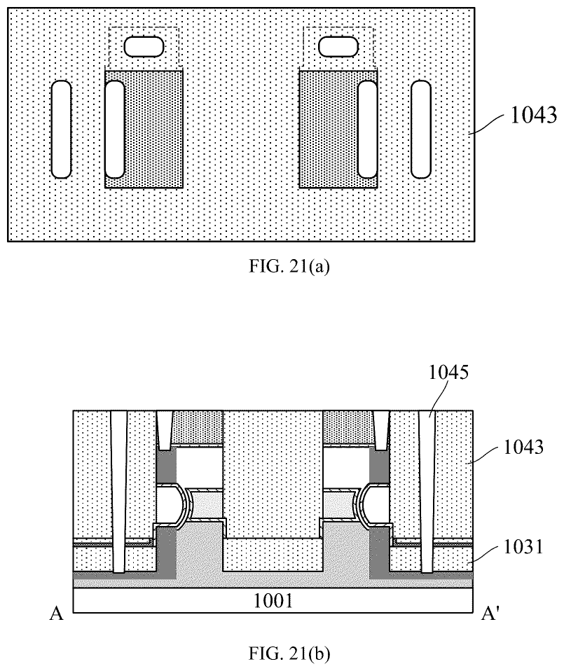

For example, as shown in FIGS. 21(a) and 21(b), a dielectric layer 1043 may be formed on the substrate, for example, by deposition followed by planarization. Then, a contact hole may be formed and filled with a conductive material such as metal to form a contact portion 1045. The contact portion 1045 may include a contact portion that penetrates the spacer 1017 and the etching stop layer 1009 to connect to the upper source/drain portion, a contact portion that penetrates the dielectric layer 1043 and the isolation layer 1031 to connect to the contact region of the lower source/drain portion, and a contact portion that penetrates the dielectric layer 1043 to connect to the landing pad of the conductive layer 1041.

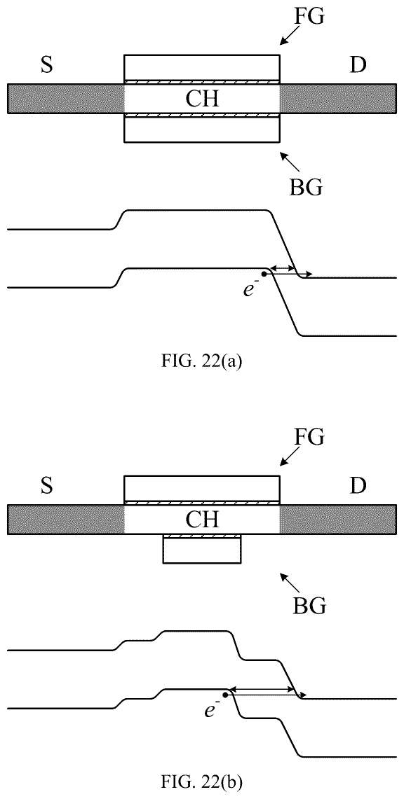

FIGS. 22(a) and 22(b) respectively show an energy band diagram of an n-type device according to a comparative example and an energy band diagram of an n-type device according to an embodiment of the present disclosure.

As shown in FIG. 22(a), in the n-type device according to the comparative example, a source region S and a drain region D may be defined by n-type doping in the active region (the source region S and the drain region D are interchangeable, so they may be collectively referred to as the source/drain region). A channel region CH may be formed between the source region S and the drain region D. A first gate stack FG (which may be referred to as a front gate) may be formed on one side of the channel region CH, and a second gate stack BG (which may be referred to as a back gate) may be formed on the other side of the channel region CH. Usually, the first gate stack FG and the second gate stack BG may have the same gate length and may be substantially aligned on opposite sides of the channel region CH. Due to such arrangement, a bandgap (as shown by the bidirectional arrow in the figure) on the side of the drain region D may be reduced, and thus electrons are prone to tunneling, leading to GIDL.

As shown in FIG. 22(b), in the n-type device according to the embodiment of the present disclosure, a distance between an edge of the first gate stack FG and adjacent source/drain region S or D is greater than a distance between a corresponding edge of the second gate stack BG and adjacent source/drain region S or D. Due to such position offset, the bandgap may be increased relative to the situation shown in FIG. 22(a), so that it relatively difficult for electrons to tunnel and thus suppressing GIDL.

FIGS. 22(a) and 22(b) illustrate the principle of suppressing GIDL in embodiments of the present disclosure by using the n-type device as an example. The same applies to the p-type device.

In the above embodiment, the device has substantially the same or similar configuration on the source region side and the drain region side. However, the present disclosure is not limited to this. From the perspective of suppressing GIDL, the concept of the present disclosure may be applied to the drain region side.

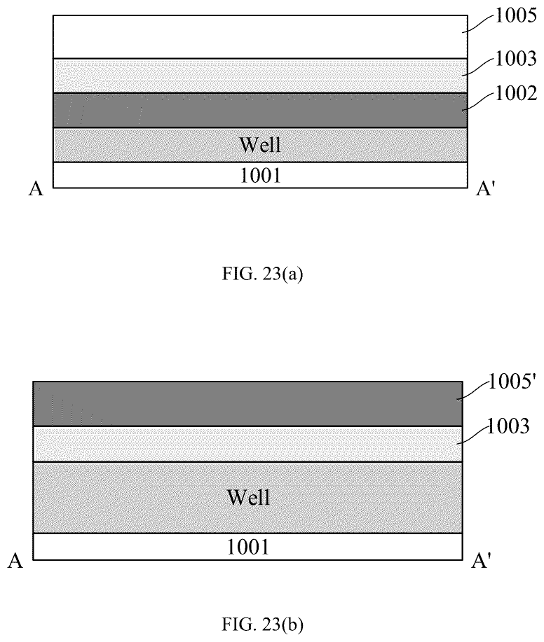

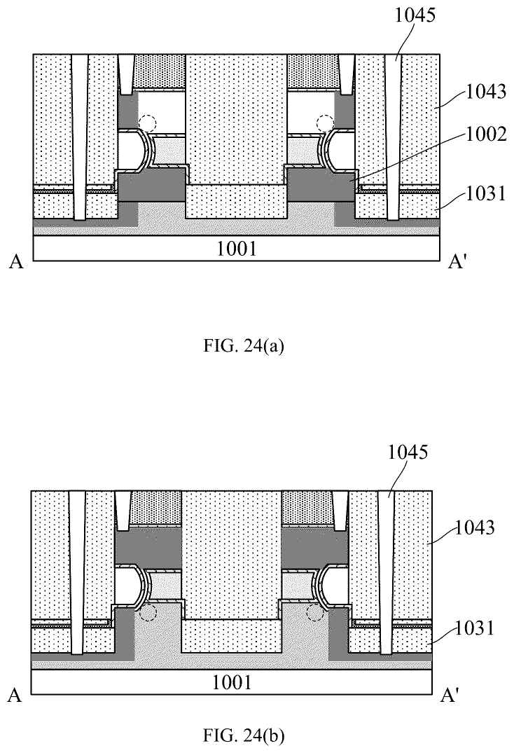

FIGS. 23(a) to 24(b) show schematic diagrams of some stages in a process of manufacturing a semiconductor device according to another embodiment of the present disclosure. The following mainly describes the differences between this embodiment and the above embodiments.

As shown in FIG. 23(a), the substrate 1001 may be provided as described above, and a well region may be formed in the substrate 1001. A first material layer 1002, a second material layer 1003, and a third material layer 1005 may be formed on the substrate 1001 by epitaxial growth, for example. The first material layer 1002 may be used to define the position of the lower source/drain portion, with a thickness in a range of about 20 nm to 200 nm. The first material layer 1002 may be doped in situ during growth, with a doping concentration in a range of about 1E19 cm⁻³ to 1E21 cm⁻³.

Adjacent layers among the substrate 1001 and layers formed on the substrate 1001 may have etching selectivity relative to each other. For example, in the case that the substrate 1001 is the silicon wafer, the first material layer 1002 may include Si.

For the second material layer 1003 and the third material layer 1005, please refer to the description in the above embodiments.

Alternatively, as shown in FIG. 23(b), the substrate 1001 may be provided as described above and a well region may be formed in the substrate 1001. A second material layer 1003 and a third material layer 1005 may be formed on the substrate 1001 by epitaxial growth, for example. Unlike the above embodiments, the third material layer 1005 may be doped in situ during growth, with a doping concentration in a range of about 1E19 cm⁻³ to 1E21 cm⁻³.

Afterwards, the process may be performed according to the above embodiments.

Starting from the stack shown in FIG. 23(a), a device shown in FIG. 24(a) may be obtained. Unlike the case that respective parts of the first material layer and the third material layer adjacent to the second gate stack may be low doped (relative to the source/drain portion) or substantially unintentionally doped in the above embodiments, only the part of the third material layer adjacent to the second gate stack may be low doped or substantially unintentionally doped (as shown in the dashed circle in the figure), while the part of the first material layer adjacent to the second gate stack may be heavily doped (and thus become a part of the source/drain portion). In this example, the upper source/drain portion may become the drain.

In addition, starting from the stack shown in FIG. 23(b), a device shown in FIG. 24(b) may be obtained. Similarly, only the part of the first material layer adjacent to the second gate stack may be low doped or substantially unintentionally doped (as shown in the dashed circle in the figure), while the part of the third material layer adjacent to the second gate stack may be heavily doped (and thus become a part of the source/drain portion). In this example, the lower source/drain portion may become the drain.

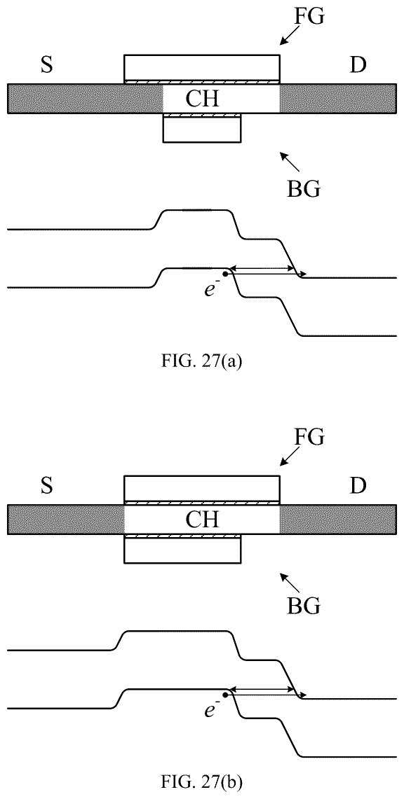

FIG. 27(a) shows an energy band diagram of an n-type device according to this embodiment. The gate stacks FG and BG shown in FIG. 27(a) may be the same as shown in FIG. 22(b), except that on one side of the channel portion (specifically, the source S side), source/drain doping (in the case of n-type devices, n-type heavily doping) may extend to the edge of the second gate stack BG. It may be seen that the benefit of an increase in bandgap to suppress GIDL may still be maintained on the drain D side; meanwhile, on the source S side, the external resistance may be reduced and the performance may be improved due to the source/drain doping distribution.

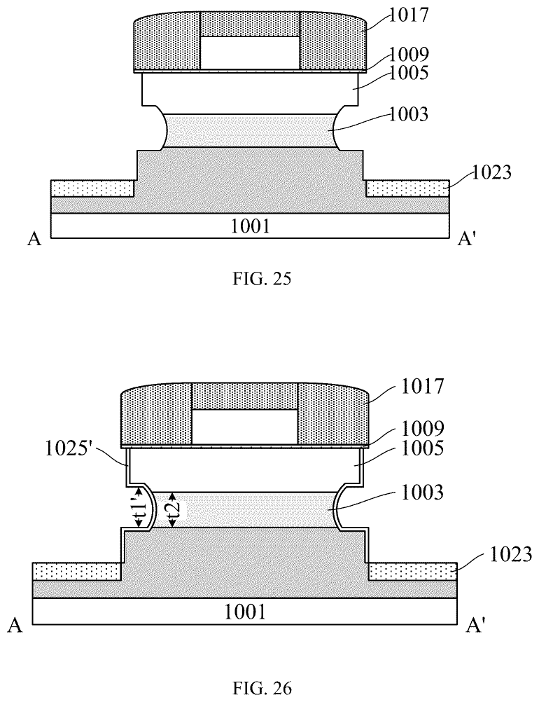

FIGS. 25 to 26 show schematic diagrams of some stages in a process of manufacturing a semiconductor device according to another embodiment of the present disclosure.

In the above embodiment, in the etching back process described in conjunction with FIG. 9, the depth of the recess portion being etched upwards may be substantially identical to the depth of the recess portion being etched downwards. Unlike this, in this embodiment, as shown in FIG. 25, the depth of the recess portion being etched upwards may be different from the depth of the recess portion being etched downwards. This may be achieved by selecting materials for the first and third material layers, selecting etching recipes, and the like. FIG. 25 only shows the case that the depth of the recess portion being etched upwards is greater than the depth of the recess portion being etched downwards, but it is also possible for the depth of the recess portion being etched downwards to be greater than the depth of the recess portion being etched upwards.

Then, as shown in FIG. 26, a first active layer 1025′ may be formed by selective epitaxial growth, for example. Similarly, after the growth of the first active layer 1025, a height t1′ of the recess portion may be different from the thickness t2 of the second material layer 1003, especially t1′ may be greater than t2. In this example, a distance between an upper edge of the thickness t1′ and an upper edge of the thickness t2 may be greater than a distance between a lower edge of the thickness t1′ and a lower edge of the thickness t2 (this distance may even be zero). According to other embodiments, the distance between the lower edge of the thickness t1′ and the lower edge of the thickness t2 may be greater than the distance between the upper edge of the thickness t1′ and the upper edge of the thickness t2 (this distance may even be zero).

Then, the process may be performed according to the above embodiments. In the resultant device, at one end of the channel portion in the vertical direction, the distance between the edge of the first gate stack and the adjacent source/drain portion is less than the distance between the edge of the second gate stack and the adjacent source/drain portion (this source/drain portion may become a drain). At the other end of the channel portion in the vertical direction, the edges of the first and second gate stacks may be relatively close to each other, and even aligned in the lateral direction (in the x-direction).

FIG. 27(b) shows an energy band diagram of the n-type device according to this embodiment. In this embodiment, respective edges of the first gate stack FG and the second gate stack BG on the source S side may be offset relatively small from each other (or even aligned with each other), while respective edges of the first gate stack FG and the second gate stack BG on the drain D side may be offset relatively large from each other, especially the edge of the first gate stack FG is closer to the doping distribution of the drain D compared to the edge of the second gate stack BG. It may be seen that the benefit of an increase in bandgap to suppress GIDL may still be maintained on the drain D side.

In the above embodiment, the first and second gate stacks are electrically connected to each other through the conductive layer 1041, and may receive the same electrical signal through the contact portion of the conductive layer 1041. However, the present disclosure is not limited to this. For example, the conductive layer 1041 may not be formed to electrically connect the first and second gate stacks to each other, and different electrical signals may be applied to the first and second gate stacks, respectively.

In the above embodiment, two devices are formed based on a single ridge structure. This is beneficial for simplifying manufacturing. However, the present disclosure is not limited to this. For example, a single device may be formed based on a single ridge structure. In this case, the single ridge structure may be similar to the stack part below the above single spacer 1017, and the processing on the single ridge structure is similar to the processing on the stack part. The difference is that when processing the outer side of the channel portion, a sidewall of the single ridge structure on the side of the hard mask layer 1013 or the mandrel pattern may be shielded by another material layer.

The semiconductor device according to embodiments of the present disclosure may be applied to various electronic apparatuses. For example, an integrated circuit (IC) may be formed based on such semiconductor devices, and an electronic apparatus may be constructed in this way. Therefore, the present disclosure further provides an electronic apparatus including the semiconductor device described above. The electronic apparatus may further include a display screen cooperating with the integrated circuit, a wireless transceiver cooperating with the integrated circuit, and other components. The electronic apparatus may include, for example, a smart phone, a personal computer (PC), a tablet computer, a wearable intelligence apparatus, and a mobile power supply.

According to embodiments of the present disclosure, a method of manufacturing a system on chip (SoC) is further provided. This method may include the above-mentioned method. Specifically, a variety of devices may be integrated on the chip, at least some of which are manufactured according to the methods of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may also design a method that is not completely identical to the methods described above. In addition, although the various embodiments are described above separately, this does not mean that the measures in the various embodiments may not be advantageously used in combination.

Embodiments of the present disclosure have been described above. However, embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A semiconductor device, comprising:
a vertical channel portion on a substrate;
source/drain portions respectively located at upper and lower ends of the channel portion relative to the substrate; and
a first gate stack on a first side of the channel portion in a first direction lateral to the substrate and a second gate stack on a second side of the channel portion in the first direction, wherein the second side is opposite to the first side,
wherein a distance between an upper edge of an end of the first gate stack facing the channel portion in a vertical direction and a corresponding source/drain portion is less than a distance between a corresponding one of an upper edge and a lower edge of an end of the second gate stack facing the channel portion in the vertical direction and a corresponding source/drain portion, and/or a distance between a lower edge of an end of the first gate stack facing the channel portion in a vertical direction and a corresponding source/drain portion is less than a distance between a corresponding one of an upper edge and a lower edge of an end of the second gate stack facing the channel portion in the vertical direction and a corresponding source/drain portion.

2. The semiconductor device according to claim 1, wherein a gate length of the first gate stack is greater than a gate length of the second gate stack.

3. The semiconductor device according to claim 1, wherein the semiconductor device is an n-type device, and a threshold voltage of a part of the channel portion adjacent to the first gate stack is lower than a threshold voltage of a part of the channel portion adjacent to the second gate stack; or
the semiconductor device is a p-type device, and a threshold voltage of a part of the channel portion adjacent to the first gate stack is higher than a threshold voltage of a part of the channel portion adjacent to the second gate stack.

4. The semiconductor device according to claim 1, wherein the semiconductor device is an n-type device, and an effective work function of the first gate stack is less than an effective work function of the second gate stack; or
the semiconductor device is a p-type device, and an effective work function of the first gate stack is greater than an effective work function of the second gate stack.

5. The semiconductor device according to claim 1, wherein a material and/or a thickness of a gate dielectric layer in the first gate stack are/is different from a material and/or a thickness of a gate dielectric layer in the second gate stack.

6. The semiconductor device according to claim 1, wherein a metal element of a gate conductor layer in the first gate stack is different from a metal element of a gate conductor layer in the second gate stack.

7. The semiconductor device according to claim 1, wherein the first gate stack is self-aligned with the second gate stack in the first direction.

8. The semiconductor device according to claim 7, wherein an offset of the upper edge of the end of the first gate stack facing the channel portion in the vertical direction relative to the upper edge of the end of the second gate stack facing the channel portion in the vertical direction is substantially identical to an offset of the lower edge of the end of the first gate stack facing the channel portion in the vertical direction relative to the lower edge of the end of the second gate stack facing the channel portion in the vertical direction.

9. The semiconductor device according to claim 1, further comprising:
a first semiconductor layer and a second semiconductor layer spaced apart from each other in the vertical direction; and
a third semiconductor layer extending from a sidewall of the first semiconductor layer to a sidewall of the second semiconductor layer,
wherein the channel portion is formed in a part of the third semiconductor layer located between the first semiconductor layer and the second semiconductor layer in the vertical direction, and
wherein the source/drain portions are formed in the first semiconductor layer and the third semiconductor layer on the sidewall of the first semiconductor layer as well as in the second semiconductor layer and the third semiconductor layer on the sidewall of the second semiconductor layer, respectively.

10. The semiconductor device according to claim 9, wherein a part of at least one of the first semiconductor layer and the second semiconductor layer close to the second gate stack is low doped or substantially unintentionally doped.

11. The semiconductor device according to claim 1, further comprising:
a protective layer covering an end of the channel portion in a second direction lateral to the substrate, wherein the second direction intersects with the first direction.

12. The semiconductor device according to claim 11, further comprising:
a conductive layer that electrically connects the first gate stack and the second gate stack to each other, wherein the conductive layer surrounds the protective layer.

13. The semiconductor device according to claim 12, wherein the conductive layer is only provided on opposite sides of the channel portion in the second direction.

14. The semiconductor device according to claim 11, wherein the first gate stack comprises a first gate dielectric layer and a first gate conductor layer, wherein the first gate dielectric layer is located between the first gate conductor layer and the channel portion, as well as between the first gate conductor layer and the protective layer, and
the second gate stack comprises a second gate dielectric layer and a second gate conductor layer, wherein the second gate dielectric layer is located between the second gate conductor layer and the channel portion, as well as between the second gate conductor layer and the protective layer.

15. The semiconductor device according to claim 1, wherein a gate dielectric layer in the first gate stack is only provided on the first side of the channel portion, and a gate dielectric layer in the second gate stack is only provided on the second side of the channel portion.

16. The semiconductor device according to claim 1, wherein the channel portion comprises a curved nanosheet or nanowire with a C-shape cross-section.

17. The semiconductor device according to claim 16, wherein the curved nanosheet or nanowire has a substantially uniform thickness.

18. The semiconductor device according to claim 1, wherein both ends of the channel portion in a second direction lateral to the substrate present an inward-recessed C-shape, wherein the second direction intersects with the first direction.

19. The semiconductor device according to claim 1, wherein at least one of the channel portion and the source/drain portions comprises a single crystal semiconductor material.

20. The semiconductor device according to claim 16, wherein a plurality of semiconductor devices are provided on the substrate, and C-shapes of at least one pair of semiconductor devices among the plurality of semiconductor devices face away from each other.

21. The semiconductor device according to claim 20, wherein respective channel portions of the pair of semiconductor devices are substantially coplanar.

22. A method of manufacturing a semiconductor device, comprising:
providing a stack of a first material layer, a second material layer, and a third material layer on a substrate, wherein the stack has a first side and a second side opposite to each other in a first direction lateral to the substrate;
recessing, on the first side and the second side, a sidewall of the second material layer in the first direction relative to a sidewall of the first material layer and a sidewall of the third material layer, so as to define a first recess portion;
further etching, on the first side and the second side, the first material layer, the second material layer, and the third material layer, so as to increase a size of the first recess portion in a vertical direction;
forming a channel layer in the first recess portion;
forming a first gate stack in the first recess portion in which the channel layer is formed;
forming, in the stack, a strip opening extending in a second direction lateral to the substrate, so as to divide the stack into two parts respectively located on the first side and the second side, wherein the second direction intersects with the first direction; and
removing the second material layer through the opening, and forming a second gate stack in a space released due to a removal of the second material layer,
wherein a size of the first gate stack in the vertical direction is greater than a size of the second gate stack in the vertical direction.

23. The method according to claim 22, wherein the method further comprises: before defining the first recess portion,
recessing, on a third side and a fourth side of the stack in the second direction, a sidewall of the second material layer in the second direction relative to a sidewall of the first material layer and a sidewall of the third material layer, so as to define a second recess portion, wherein the third side and the fourth side are opposite to each other; and
forming a first position retaining layer in the second recess portion.
wherein the method further comprises: after forming the channel layer,
forming a second position retaining layer in the first recess portion;
forming a dopant source layer on a sidewall of the stack; and
driving a dopant in the dopant source layer into the first material layer and the third material layer, so as to form source/drain portions, and
wherein forming the first gate stack comprises:
removing the second position retaining layer; and
forming, in the first recess portion, the first gate stack in a space released due to a removal of the second position retaining layer.

24. The method according to claim 23, further comprising:
selectively etching the first position retaining layer to release a part of a space in the second recess portion, while the first position retaining layer still covers an end of the channel layer in the second direction; and
forming a conductive layer, wherein the part of the space released in the second recess portion is filled with the conductive layer, so that the first gate stack and the second gate stack are electrically connected to each other.

25. The method according to claim 23, further comprising:
controlling a degree of driving the dopant into the first material layer and the third material layer, so that the dopant substantially does not reach parts of the first material layer and the second material layer close to the second gate stack.

26. The method according to claim 22, wherein the channel layer is formed by selective epitaxial growth.

27. The method according to claim 22, wherein a size of the first recess portion that increases downwards in the vertical direction is substantially equal to a size of the first recess portion that increases upwards in the vertical direction.

28. An electronic apparatus, comprising the semiconductor device according to claims 1.

29. The electronic apparatus according to claim 28, wherein the electronic apparatus comprises: a smart phone, a personal computer, a tablet computer, a wearable intelligence apparatus, an artificial intelligence apparatus, and a mobile power supply.
